(19) United States
(12) Patent Application Publication
(10) Pub. No.: US 2025/0237702 A1
(43) Pub. Date: Jul. 24, 2025

(54) ALTERNATOR MONITORING SYSTEMS AND METHODS

(71) Applicant: Nanyang Technological University, Singapore (SG)

(72) Inventors: Srikanth NARASIMALU, Singapore (SG); Alok Kumar VERMA, Singapore (SG); Santhanakrishnan Mahesh RAMANATHAN, Singapore (SG)

(21) Appl. No.: 18/848,109

(22) PCT Filed: Mar. 24, 2023
(86) PCT No.: PCT/SG2023/050199

§ 371 Date: Sep. 17, 2024

(30) Foreign Application Priority Data
Mar. 25, 2022 (SG) 10202203111U

(51) Int. Cl. G01R 31/34; G01R 15/20; G01R 19/00; G01R 19/02; G01R 19/04; G01R 31/00

(52) U.S. Cl. CPC G01R 31/343; G01R 15/202; G01R 19/0038; G01R 19/02; G01R 19/04; G01R 31/007

(57) ABSTRACT

Systems and methods for monitoring an alternator are described. A system for monitoring an alternator comprises: a current sensor configured to measure a current signal from the alternator over time; and a controller configured to: extract parameters from the current signal; and analyze the parameters and thereby identify a potential fault in the alternator.

### TECHNICAL FIELD

The present disclosure relates to monitoring alternators, and in particular to detection and prediction of faults in alternators.

### BACKGROUND

Alternators are the major components of any industry which influence the production and power generation process. The faults in alternators may lead to expensive and catastrophic failures, which not only affect the manufacturers but also to the users. These alternator systems are consisting of various components and can be exposed to the different kind of faults. So, early detection of the faults is essential to avoid such losses.

The move towards more electrification in the automotive sector requires the electrical system architectures to be reliable and robust. In particular, there is a strong emphasis on the development of highly reliable electromechanical systems for on-board power generation and actuation systems with increased availability. The key components in the automotive electromechanical systems include alternators and mechanical prime mover or load. The faults in any of the alternator components may lead to expensive and catastrophic failures, which may affect the availability of automotive electromechanical system.

Modern passenger vehicles use motors, electronic control units (ECU) with different sensors and electromechanical actuators, and all of them required an efficient and reliable power source. The alternator is virtually a heart of every automotive based electric power generation and storage (EPGS) system. The faults in an alternator may lead to expensive and catastrophic failures, which not only affect the auto manufacturers but also to the consumers. Timely and accurate detection of alternator faults will not only help the consumers and passengers but, it will also significantly decrease the warranty cost for the manufacturers. Sometimes, abnormal driving may lead to various abnormal condition inside the system, that result faults in the alternator such as broken rotor bar, shaft misalignment, bearing, stator winding faults, and rectifier faults in these systems. In order to categorize the weakest component in the electromechanical rotating system, statistical studies about the machine faults are conducted by different groups such as EPRI (Electric Power Research Institute) and IEEE. The faults in alternator components can be distinguished as mechanical and electrical faults.

Approximately 25-35% of rotating machines failures are due to stator winding faults. The short circuit faults in the stator winding occur when the insulation of the wires breakdown or the diodes get shorted out due to over-heating or over-voltage.

The open circuit faults in the winding or rectifier occurs due to corrosion of the winding and diodes or may be due to the breaking of the wires. Frequency spectrum of the output voltage signal to detect the open circuit faults in the uncontrolled 3-@ rectifier has been used to detect this. Negative sequence current from the stator winding to detect the open circuit faults were also used. However, recursive least square method to assess the resistance of the stator winding for open circuit fault detection were also demonstrated. Further, phase voltage was compared to detect the open circuit faults in the insulated-gate bipolar transistor (IGBT). To mimic/model the open circuit faults, the large resistance can be used in the series of the phase winding or in the rectifier. Whereas to model the short circuit fault a small resistance in the parallel with the diode can be used. The parameters from various medium such as voltage, current, flux, vibration, temperature, angular speed, torque, acoustic can be used to detect the faults in alternator. In the field of rotating machinery, misalignment is also one of the most important and easily encountered fault. Misalignment is a condition in any rotating machinery where the centre lines of coupled shafts do not coincide with each other and this result to the failure of the system. Rotor failure due to broken rotor bars are approximately 5-10% of total machine failures. Some of the mere consequences of broken rotor bar are poor starting performances, excessive vibrations, higher thermal stress, or torque fluctuation.

As per the IEEE standard 493-1997 and statistical study of EPRI, bearing defects also are the one of the common mechanical failures in rotating machines which constitute more than 40-45% of all defect. Efficient methods like condition monitoring and diagnosis of machines faults are used in modern industries to detect the faults in a rotating machine such as motor, generator, and alternator. These techniques require monitoring of different parameters using different sensors. Existing industrial environment already has a variety of sensors such as vibration, speed, voltage, and temperature that can be used for monitoring purposes. Large number of researches have been published in the field of fault diagnosis of rotating machines, and most of the work has been done on vibration monitoring of the machine to detect and classify the types of fault. However, in some of the previous work used motor current signature analysis (MCSA), by identification of harmonic components and pattern recognition are one of the latest key methods to detect the electrical faults such as short-circuit faults in the machines.

### SUMMARY

According to a first aspect of the present disclosure, a system for monitoring an alternator is provided. The system comprises: a current sensor configured to measure a current signal from the alternator over time; and a controller configured to: extract parameters from the current signal; and analyze the parameters and thereby identify a potential fault in the alternator.

The current signature analysis is a non-invasive, cheaper, and does not require extra sensors because current sensors are already being used to monitor for protection and control purposes. Non-invasive sensor such as current probe to detect all kind of the electrical and mechanical faults for the rotating machines in the real-time is provided by embodiments of the present invention. Application of non-invasive current sensor method results in considerable cost savings by reducing planned outage of machinery, reducing downtime for repair, and improving reliability and safety.

The parameters extracted from the current signal may comprise time domain features.

The parameters extracted from the current signal may comprise frequency domain or envelope features. The envelope features may be extracted by applying a bandpass filter and/or applying a Hilbert transform.

The parameters extracted from the current signal may comprise entropy features and/or time-frequency domain features.

In an embodiment, the current sensor is a contactless current sensor. This provides for non-invasive measurement of the current without affecting the operation of the alternator. Further, this allows the system to be retrofitted to existing systems.

In an embodiment, the system further comprises an interface module configured to generate an alert in response to identifying a potential fault in the alternator.

In an embodiment, the system further comprises a communication interface module configured to send the extracted parameters to a remote server. The remote server may be configured to further analyze the extracted parameters, for example, to set parameter thresholds for use by the controller or to train machine learning models used by the controller for the analysis.

In an embodiment, the controller is configured to analyze the parameters by comparing the parameters with one or more thresholds.

In an embodiment, the controller is configured to analyze the parameters using a machine learning algorithm.

According to a second aspect of the present disclosure, a method of monitoring an alternator is provided. The method comprises: receiving a time varying current signal from the alternator; extracting parameters from the current signal; and analyzing the parameters to identify a potential fault in the alternator.

In an embodiment, the parameters extracted from the current signal comprise time domain features.

In an embodiment, the parameters extracted from the current signal comprise frequency domain or envelope features.

In an embodiment, the parameters comprise envelope features, and wherein extracting the envelope features from the current signal comprises applying a bandpass filter and/or applying a Hilbert transform.

In an embodiment, the parameters extracted from the current signal comprise entropy features and/or time-frequency domain features.

In an embodiment, the method further comprises generating an alert in response to identifying a potential fault in the alternator.

In an embodiment, the method further comprises sending the extracted parameters to a remote server.

In an embodiment, analyzing the parameters comprises comparing the parameters with one or more thresholds.

In an embodiment, analyzing the parameters comprises using a machine learning algorithm.

According to a third aspect of the present disclosure, a computer readable medium carrying processor executable instructions which when executed on a processor cause the processor to carry out a method described above is provided.

### BRIEF DESCRIPTION OF THE DRAWINGS

In the following, embodiments of the present invention will be described as non-limiting examples with reference to the accompanying drawings in which:

FIG. 1 is a block diagram showing an alternator monitoring system according to an embodiment of the present invention;

FIG. 2 is a block diagram showing a controller of an alternator monitoring system according to an embodiment of the present invention;

FIG. 3 is a flowchart showing an alternator monitoring method according to an embodiment of the present invention;

FIG. 4 is a flowchart showing an alternator monitoring method according to an embodiment of the present invention;

FIG. 5 is a graph showing time series signals of current signal for healthy and stator winding fault;

FIG. 6A to FIG. 6G show time domain parameters extracted from different alternators;

FIG. 7 is a graph showing weighted average of entropy and speed for different alternators;

FIG. 8A to 8J show spectrum analysis graphs for current signals of different alternators;

FIG. 9 is a flow chart showing a method of envelope analysis for detection of faults in alternators according to an embodiment of the present invention;

FIG. 10A to FIG. 10C are graphs showing envelope analysis using a Hilbert transform for healthy and alternators; and

FIG. 11A and FIG. 11B show discrete wavelet transform analysis of signals from a healthy alternator and a faulty alternator.

### DETAILED DESCRIPTION

The present disclosure provides systems and methods for monitoring alternators, and particular embodiments relate to automotive alternators. The systems and methods monitor distinct operating conditions of an alternator using a controller board interfaced with current sensor. The system may be implemented as a low cost, IoT based processor board known as smart alternator monitoring system (SAMS) interfaced with the current sensor which generates specific signatures. The methods may include data analytics and machine learning techniques applied on the generated signals to identify and predict the critical operating conditions of an alternator in real-time. The identified and predicted signature parameters from the developed system may be send to a remote server through a cloud-based system for access and decision making based on the operating conditions. Software may be implemented to provide a graphical user interface (GUI) for a dashboard to allow technicians at local and remote locations to identify the critical conditions of the alternator through alarm setting.

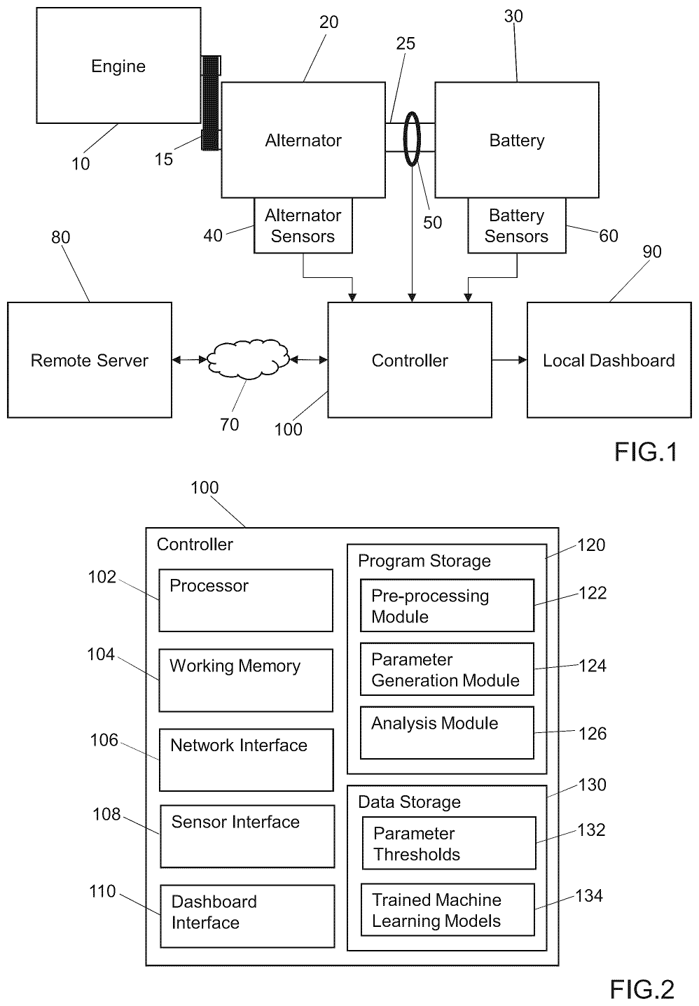

FIG. 1 is a block diagram showing an alternator monitoring system according to an embodiment of the present invention. As shown in FIG. 1, an alternator 20 is coupled to an engine 10 by a belt 15. When the engine 10 is running, the belt 15 causes a rotor of the alternator 20 to rotate relative to a stator of the alternator and thereby generate an electric current. The electric current is generated in alternator output wires 25 which are coupled to a battery 30. The alternator output wires 25 may also be coupled to other electrical loads such as electrical components of vehicle including a starter motor, ignition of the engine, lights, wipers, and an audio system of the vehicle. When the vehicle such as a bus is running, the engine 10 causes the rotor of the alternator 20 to rotate and thereby produce electrical power which is used to power the electrical loads and charge the battery 30.

A controller 100 is configured to monitor the alternator 20. Alternator sensors 40 coupled to the alternator 20 are configured to measure various operating properties of the alternator 20 such as its rotational speed, vibration, voltage and temperature. A contactless current sensor 50 is arranged to measure the current in the alternator output wires 25. Battery sensors 60 coupled to the battery are configured to measure various operating properties of the battery 30 such as its temperature, output current and voltage.

The contactless current sensor 50 may be a Hall effect sensor which is based on mutual inductance. An advantage of using a contactless current sensor is that it can be retrofitted to existing systems without the need to modify the existing system controls. This means that the alternator monitoring system can be added without affecting the warranty of the existing system.

The alternator sensors 40, the contactless current sensor 50 and the battery sensors 60 are coupled to the controller 100 and provide the controller 100 with real time data of the operating properties of the alternator, real time data of the current in the alternator output wires 25 and real time data of the operating properties of the battery 30.

As is described in more detail below, the controller 100 generates real-time features of the current, for example, time domain features, frequency domain features, and time-frequency domain features.

The controller 100 is coupled to a remote server 80 by a wireless network 70, and to a local dashboard 90. The remote server 80 may be implemented as a cloud platform to perform analysis of the operation of the alternator 20 using the extracted features. The local dashboard 90 generates alerts, for example to indicate that a fault has occurred in the alternator 20 based on the analysis of the extracted features carried out by the controller 100. A service technician may provide preventive maintenance based upon the identified and predicted signatures for operating conditions of the alternator.

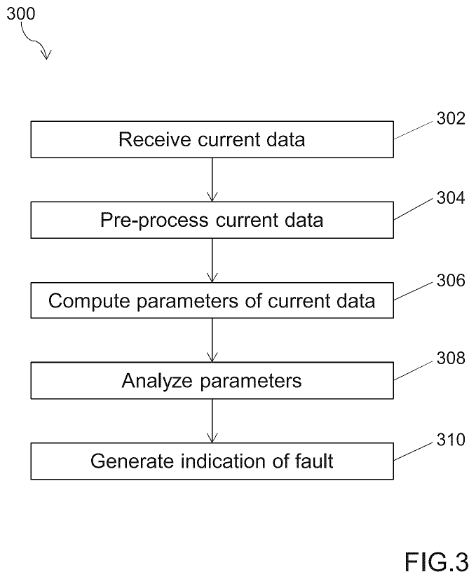

FIG. 2 is a block diagram showing a controller of an alternator monitoring system according to an embodiment of the present invention. The controller 100 may be implemented as a system-on-module or a single board computer. As shown in FIG. 2, the controller 100 comprises a processor 102, a working memory 104, a network interface 106, a sensor interface 108, a dashboard interface 110, program storage 120 and data storage 130.

The processor 102 may be implemented as one or more central processing unit (CPU) chips such as a cortex-A72 processor. The program storage 120 is a non-volatile storage device such as a solid state memory which stores computer program modules. The computer program modules are loaded into the working memory 104 for execution by the processor 102. The network interface 106 is an interface that allows the controller 100 to communicate with other devices and systems, the remote server 80. The sensor interface 108 is an interface which allows the data captured by the alternator sensors 40, the contactless current sensor 50 and the battery sensors 60 to be received and processed by the controller 100. The dashboard interface 110 is configured to allow the controller to generate indications and/or alerts for a user or driver of the vehicle via the local dashboard 90.

The program storage 120 stores a pre-processing module 122, a parameter generation module 122, and an analysis module 124. The computer program modules cause the processor 102 to execute various alternator monitoring methods described in more detail below. The program storage 120 may be referred to in some contexts as computer-readable storage media and/or non-transitory computer-readable media. As depicted in FIG. 2, the computer program modules are distinct modules which perform respective functions implemented by the controller 100. It will be appreciated that the boundaries between these modules are exemplary only, and alternative embodiments may merge modules or impose an alternative decomposition of the functionality of modules. For example, the modules discussed herein may be decomposed into sub-modules to be executed as multiple computer processes and, optionally, on multiple computers. Moreover, alternative embodiments may combine multiple instances of a particular module or sub-module. It will also be appreciated that, while a software implementation of the computer program modules is described herein, these may alternatively be implemented as one or more hardware modules (such as field-programmable gate array(s) or application-specific integrated circuit(s)) comprising circuitry which implements equivalent functionality to that implemented in software.

The data storage 130 stores parameter thresholds 132 and trained machine learning models 134. The parameter thresholds 132 and the trained machine learning models 134 are used by the analysis module 126 to analyze parameters of the sensed current signals to determine information on the condition of the alternator. The parameter thresholds 132 may be determined by the remote server 80 and sent to the controller 100 via the network interface 106. Similarly, the trained machine learning modules may be trained on the remote server 80 and sent to the controller 100 via the network interface 106.

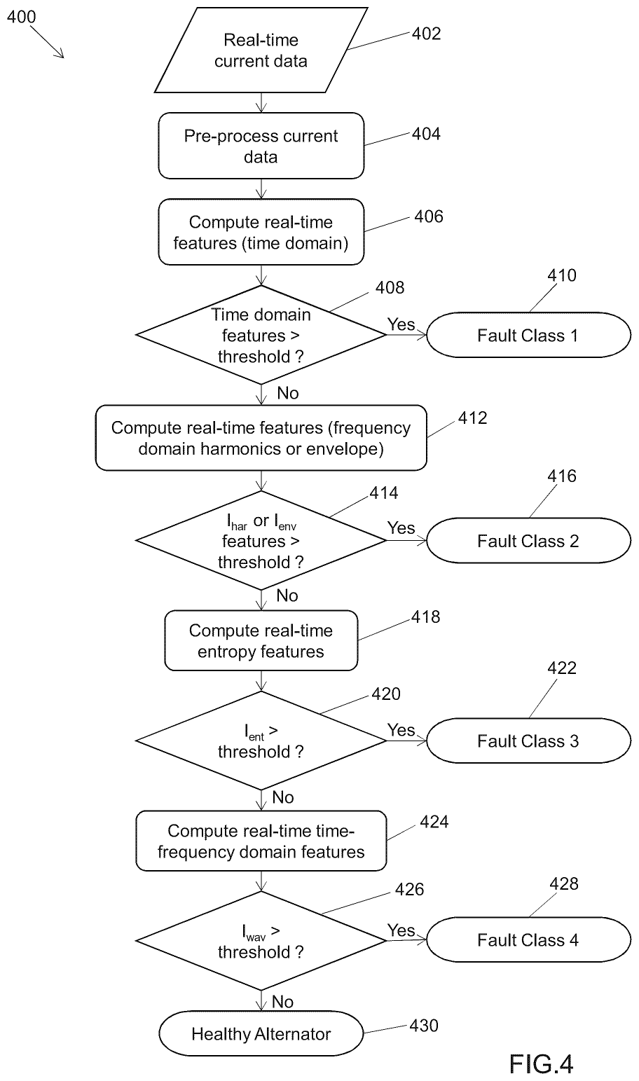

FIG. 3 is a flowchart showing an alternator monitoring method according to an embodiment of the present invention. The method 300 shown in FIG. 3 is implemented in the controller 100 shown in FIG. 2.

In step 302, the controller 100 receives current data from the contactless current sensor 50. The current data may be received and processed in real-time or near real-time.

In step 304, the pre-processing module 122 is executed by the processor 102 to pre-process the current data. The pre-processing may comprise filtering the received signals to remove noise. The received signals may be influenced by noise such as powerline noise and mechanical noise. The noise can be removed by filtering, for example, a notch filter may be used to remove powerline noise.

In step 306, the parameter generation module 134 is executed by the processor 102 to compute parameters of the current data. The computation of parameters of the current data comprises extracting features from the current signals. The signals can be signals can be analyzed in time domain, frequency domain analysis, entropy analysis, envelop analysis and time-frequency domain analysis approach by using data analytics/signal processing techniques. Time-domain and frequency domain analysis is mostly used here for feature extraction. Different time domain, entropy, envelop and frequency domain analysis features which can be extracted from sensor includes: (1) RMS value, (2) Peak value, (3) Crest factor, (4) Variance, (5) Skewness and (6) Kurtosis, (7) entropy, (8) spectrum analysis, (9) envelop using Hilbert transform and (10) wavelet transform based analysis.

The frequency domain analysis methods are based on the Fast Fourier transform and sometimes can be used as full spectrum. The guiding principle of frequency analysis of the signal is that the frequency spectrum of the signal has frequency components which can be directly related to the change of data. Any change in the data results in the change of these frequency components. So, this is another method used for parameter calculation.

In step 308, the analysis module 126 is executed by the processor 102 to analyze the extracted parameters. After processing the input and extracting the features from sensor signals, the parameters are used to identify and predict faults in the alternator. In some embodiments, the analysis is carried out using a trained machine learning model 134 such as an artificial neural network, a support vector machine or a fuzzy logic to classify the condition of the alternator based on the extracted features. In other embodiments, the analysis is carried out by comparing features with stored parameter thresholds 132.

In step 310, the controller 100 generates an indication of a fault if the analysis in step 308 indicates that there is a fault. The indication of the fault may be generated as an alert to a user, for example by providing an indication on the local dashboard 90.

The calculated parameters may be sent to the remote server 80 for storage, display, and control from a remote location-based control station in addition to providing an alert to the user on the local dashboard 90. The remote server 80 may use the received parameters in further train machine learning models or to recalculate and calibrate parameter thresholds.

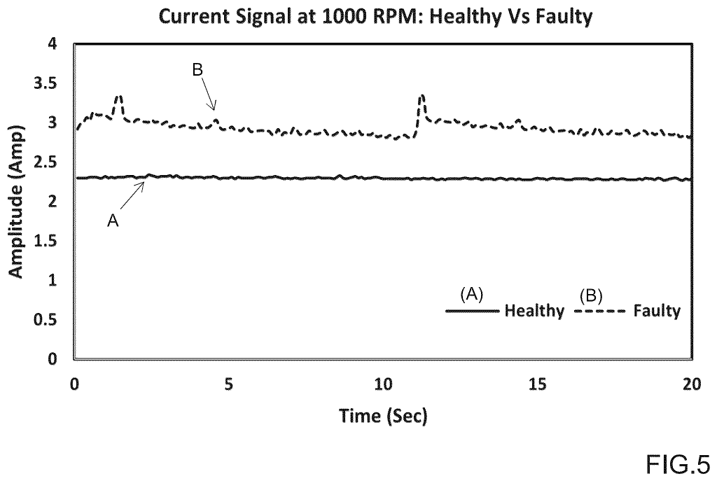

FIG. 4 is a flowchart showing an alternator monitoring method according to an embodiment of the present invention. The method 400 shown in FIG. 4 is a more detailed example of alternator monitoring in which the analysis is carried out by comparing parameter values with thresholds.

In step 402, the controller 100 receives real-time current data from the contactless current sensor 50. The real-time current data is received by the sensor interface 108 of the controller 100.

In step 404, the pre-processing module 122 is executed by the processor 102 to pre-process the current data. Step 404 of the method 400 shown in FIG. 4 corresponds to step 304 of the method 300 shown in FIG. 3.

In step 406, the parameter generation module 134 is executed by the processor 102 to compute real-time time domain features of the current data.

In step 408, the analysis module 126 is executed by the processor 102 to compare the computed time domain features with a time domain feature threshold from the stored parameter thresholds 132.

If the computed time domain features are greater than the time domain feature threshold, then the method moves to step 410 in which the alternator is identified as having a fault class 1.

If the computed time domain features are less than the time domain feature threshold, then the method moves to step 412 in which real time frequency domain harmonic features or envelope features are calculated by the parameter generation module 134 executed by the processor 102.

In step 414, the analysis module 126 is executed by the processor 102 to compare the computed frequency domain harmonic features (Iₕₐᵣ) or envelope features (Iₑₙᵥ) with a threshold from the stored parameter thresholds 132.

If the computed frequency domain harmonic features (Iₕₐᵣ) or envelope features (Iₑₙᵥ) are greater than the threshold, then the method moves to step 416 in which the alternator is identified as having a fault class 2.

If the computed frequency domain harmonic features (Iₕₐᵣ) or envelope features (Iₑₙᵥ) are less than the threshold, then the method moves to step 418 in which real time entropy features are calculated by the parameter generation module 134 executed by the processor 102.

In step 420, the analysis module 126 is executed by the processor 102 to compare the computed entropy features (Iₑₙₜ) with a threshold from the stored parameter thresholds 132.

If the computed entropy features (Iₑₙₜ) are greater than the threshold, then the method moves to step 422 in which the alternator is identified as having a fault class 3.

If the computed entropy features (Iₑₙₜ) are less than the threshold, then method moves to step 424 in which real time time-frequency domain features are calculated by the parameter generation module 134 executed by the processor 102.

In step 426, the analysis module 126 is executed by the processor 102 to compare the computed time-frequency domain features (I_{wav}) with a threshold from the stored parameter thresholds 132.

If the computed time-frequency domain features (I_{wav}) are greater than the threshold, then the method moves to step 428 in which the alternator is identified as having a fault class 4.

If the computed time-frequency domain features (I_{wav}) are less than the threshold, then the method moves to step 430 in which the alternator is identified as being healthy.

An alert may be generated and displayed to a user indicating if the alternator is identified as faulty and the class of fault identified.

Features or parameters which may be extracted in real-time in embodiments of the present invention will now be described.

Time-domain analysis includes useful feature extraction tool for health monitoring and fault diagnosis of automotive alternators. Many techniques for time-domain analysis may be implemented. Data from the alternator may be sampled at 2 KS/s. Each data set formed for one condition is in the form of an array having 2000 data points for the current signal.

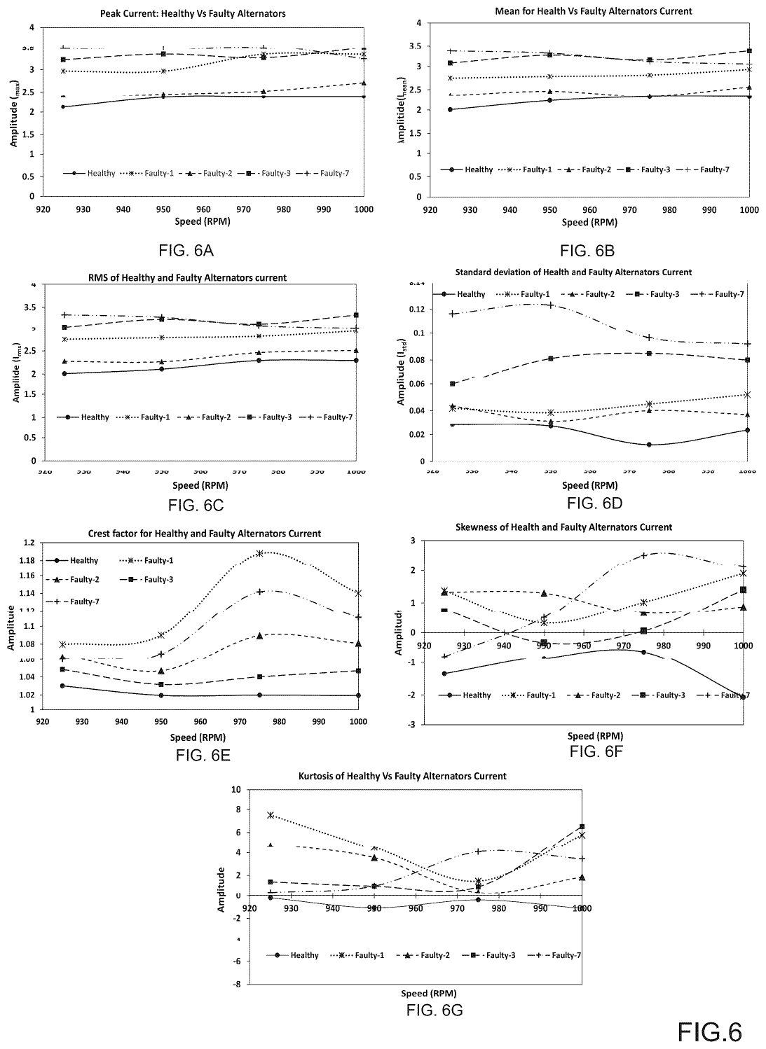

FIG. 5 is a graph showing time series signals of current signal for healthy and stator winding fault. From FIG. 5 it can be observed that healthy alternator has almost constant with little fluctuation in the amplitude of the signal however, higher amplitude and fluctuations have been observed for stator winding fault case.

The time domain features may be extracted by calculating the Root Mean Square (RMS) value (Iᵣₘₛ), the Peak Value (Iₘₐₓ), the Crest Factor (I_{cf}), Variance (Iᵥₐᵣ), Skewness (Iₛ), and Kurtosis (Vₖ).

One approach for condition monitoring includes to measure the overall intensity of the signal by estimating the Root Mean Square (RMS) level of the time domain signal. RMS value of a discrete time signal may be calculated as

$$\sqrt{\frac{1}{N} {\sum }_{i}^{N} {x}_{i}^{2}}$$

where N is number of samples and xᵢ is the amplitude of individual sample.

The peak value of any signal includes the maximum value during a given time interval. The variation of peak level of a voltage signal is indicative of change in the signal, due to the occurrence of impacts. Therefore, peak level of the signal is used to identify such occurrence. The peak value of the discrete time signal can be obtained as:

Peak value=Max(xᵢ)

The crest factor is the ratio of the peak value to RMS value and is given by:

$$Crest Factor = \frac{Peak Value}{RMS Value}$$

The crest factor is indicative of the spikiness of a signal. It is meaningful where the peak values are reasonably uniform and repeatable from one cycle to another cycle. It is often used to indicate the different faults. The crest factor for a sine wave is \sqrt{2}.

The variance of a random variable is a measure of its statistical dispersion, indicating how far from the expected values. The variance of a real-valued random variable is its second central moment. The variance of a random variable is the square of its standard deviation, given by the expression:

$$\frac{{\sum }_{i = 1}^{N} {( {x}_{i} - \overline{x} )}^{2}}{N}$$

where N is the number of samples, xᵢ is the amplitude of individual sample and x is the mean value of the time record samples. The variance of a signal gives indication about how the signal is spread around the mean.

The skewness of a distribution is given by:

$$\frac{1}{N} {\sum }_{i = 1}^{N} {[ \frac{{x}_{i} - \overline{x}}{σ} ]}^{3}$$

where σ is the standard deviation of the time record. N is the number of samples, xᵢ is the amplitude of individual sample and x̅ is the mean value of the time record samples. Skewness is the measure of symmetry of the probability density function.

Another statistical parameter, which is used as a measure of probability density function is kurtosis and is given by:

$$\frac{1}{N} {\sum }_{i = 1}^{N} {[ \frac{{x}_{i} - \overline{x}}{σ} ]}^{4}$$

It is a measure of whether the distribution is peaked or flat relative to the normal distribution. That is, data set with high kurtosis tends to have a distinct peak near the mean value. Data sets having low kurtosis tend to have a flat top near the mean value.

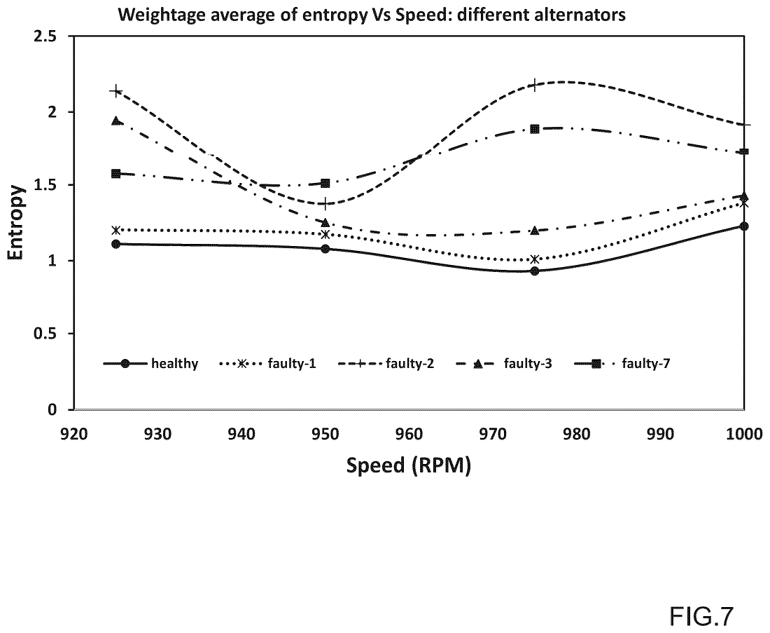

FIG. 6A to FIG. 6G show time domain parameters extracted from different alternators. FIG. 6A shows peak current, FIG. 6B shows mean current, FIG. 6C shows RMS current, FIG. 6D shows standard deviation of current, FIG. 6E shows crest factor, FIG. 6F shows skewness and FIG. 6H shows kurtosis extracted from current signals for a health alternator and faulty alternators (Faulty-1, Faulty-2, Faulty-3 and Faulty-7).

From FIG. 6A to FIG. 6G it is clear that there are differences in amplitude for healthy and faulty alternators. Therefore, it can be concluded that the discussed time domain analysis is able to differentiate between healthy and faulty alternators.

Further differentiation can be made, including identifying different faults using frequency domain, entropy, envelop and time-frequency domain analysis.

Multi-scale entropy (MSE) may be used in the analysis to tackle the nonlinearity existing in current signal as well as the uncertainty inherent in the diagnostic information. MSE refers to the calculation of entropies across a sequence of scales, which considers not only the dynamic nonlinearity but also the interaction and coupling effects between mechanical components, thus providing much more information regarding machinery operating condition in comparison with traditional single scale-based entropy. In this work, MSE is employed for feature extraction and fault recognition.

The approximate entropy (ApEn), ApEn (m, r, n) is calculated for the time series of length N, is given as follows:

$$ApEn ( m , r , N ) = \frac{1}{N - m} {\sum }_{i = 1}^{N - m} ( - ln \frac{{n}_{i}^{m + 1}}{{n}_{i}^{m}} )$$

where r is the tolerance of time series, m is pattern length and n are number of matching (including self-match). SampEn is used and it measures the regularity in series data. The SampEn is defined as

$$SampEn ( m , r , N ) = - ln ( \frac{{\sum }_{i = 1}^{N - m} {n}_{i}^{m + 1}}{{\sum }_{i = 1}^{N - m} {n}_{i}^{m}} )$$

In the MSE analysis, a coarse-grained time series is first constructed from the original time series (x₁, . . . , xᵢ, . . . , x_{N}). Consecutive coarse-grained time series with scale factor τ(τ=1; 2; . . . , N), can be constructed according to the equation

$${y}_{j}^{( τ )} = \frac{1}{τ} {\sum }_{i = ( j - 1 ) τ + 1}^{j τ} {χ}_{i}$$

$$1 \leq j \leq \frac{N}{τ} .$$

where τ is known as the scale factor and

In the calculation of average MSE, equal weightage to all the scale factors is included, but it may be necessary to put highest weightage to the highest scale factor value and the lowest to scale factor 1 (t=1) in the case of alternator fault diagnosis.

The limitation of average MSE value is overcome by weighted average (WA) and this is given by

$$W A = \frac{{\sum }_{i = 1}^{20} ( MSE for τ = 1 ) \times i}{{\sum }_{i = 1}^{20} i}$$

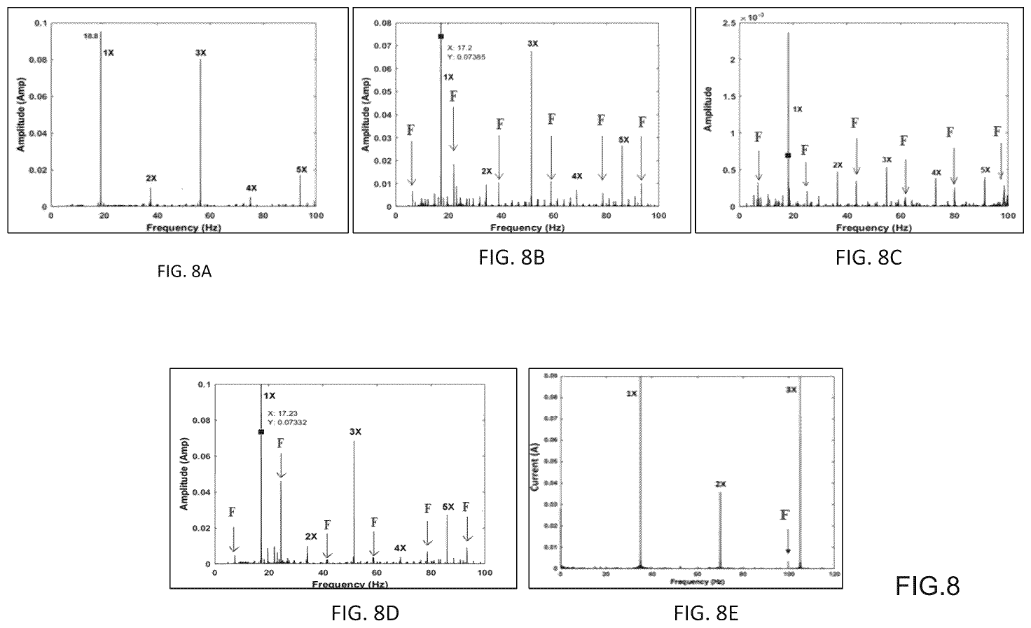

FIG. 7 is a graph showing weighted average of entropy and speed for different alternators. The justification of weighted average is quite prominent from the fact that the information related to system health is prominent at higher speeds. In all the analyzed data, it was found that the healthy motor has lower entropy state than the faulty motor.

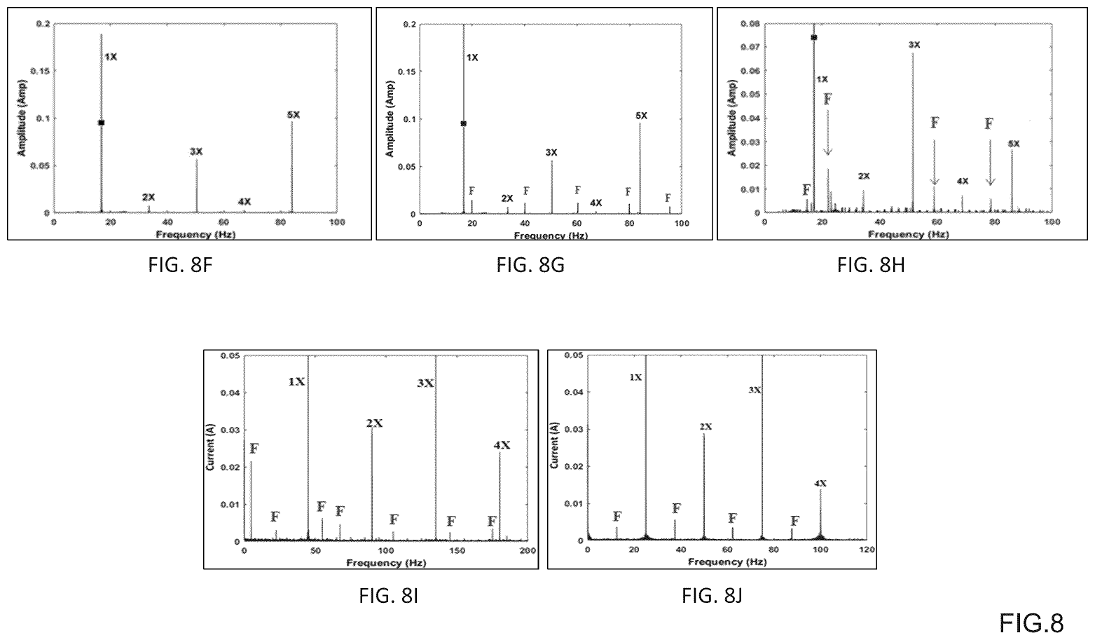

Frequency domain analysis can also be used. The purpose of this analysis is to find out the frequency content of the signals so that the relationship between the frequencies and type of faults can be established. By this method, machinery condition can be assessed by observing the presence of assumed frequency components. The amplitude of these frequency components with respect to reference signal level of healthy machines gives indication of presence of fault. In this work, Fast Fourier transform (FFT) is used to extract the frequency related features. Fourier transform is a mathematical approach used to express any periodic and nonperiodic function by an infinite series of sum of periodic exponential function. The purpose of using Fourier transform is to obtain the frequency components of the vibration and current signals. Continuous Fourier transform of an analog time varying signal x(t) is given by

$$x ( f ) = {\int }_{- ∞}^{∞} x ( t ) {e}^{- j 2 π f t} d t$$

where x(t) is time domain function and x(f) is the Fourier transform of the signal x(t). If the signal is in discrete form, discrete Fourier transform (DFT) of the signal is given by:

$$x ( f ) = {\sum }_{n = 0}^{N - 1} x ( n ) {e}^{- j 2 π f / N}$$

where N is the total number of samples in a given time record, x(n) is the discrete time signal and x (f) is the discrete Fourier transform of the signal. Fast Fourier transform (FFT) of current signals for healthy, and different faulty alternators (faulty-1, faulty-2, faulty-3, faulty-7) are shown in FIG. 8A to FIG. 8J.

FIG. 8A to 8J show spectrum analysis graphs for current signals of different alternators. FIG. 8A shows a spectrum analysis graph for current signals of a healthy alternator at 950 rpm, FIG. 8B shows a spectrum analysis graph for current signals of faulty-1 alternator at 950 rpm, FIG. 8C shows a spectrum analysis graph for current signals of faulty-2 alternator at 950 rpm, FIG. 8D shows a spectrum analysis graph for current signals of faulty-3 alternator at 950 rpm, FIG. 8E shows a spectrum analysis graph for current signals of faulty-7 alternator at 950 rpm, FIG. 8E shows a spectrum analysis graph for current signals of a healthy alternator at 1000 rpm, FIG. 8G shows a spectrum analysis graph for current signals of faulty-1 alternator at 1000 rpm, FIG. 8H shows a spectrum analysis graph for current signals of faulty-2 alternator at 1000 rpm, FIG. 8I shows a spectrum analysis graph for current signals of faulty-3 alternator at 1000 rpm, and FIG. 8J shows a spectrum analysis graph for current signals of faulty-7 alternator at 1000 rpm.

From the frequency domain analysis, it was observed that the harmonics 1X represent the electrical frequency at around 0). The harmonic ‘F’ represents the fault spectral harmonics using the current signal and that dramatically changes from healthy to different fault states. The same observation has been noticed for the repeatable results. The different fault severity can also be determined by observing the magnitude of the harmonics. Further, these fault frequencies ‘F’ were taken to detect faults.

An additional method of frequency analysis is envelope analysis. In this disclosure, two method of envelope are considered: (i) using bandpass rectification and (ii) using Hilbert transform. The first method uses filtering technique based on bandpass. The second, Hilbert transform (HT) does not involve in a domain change of the signal. HT of a signal x(t) generate another signal denoted here by y(t) will be in the same domain.

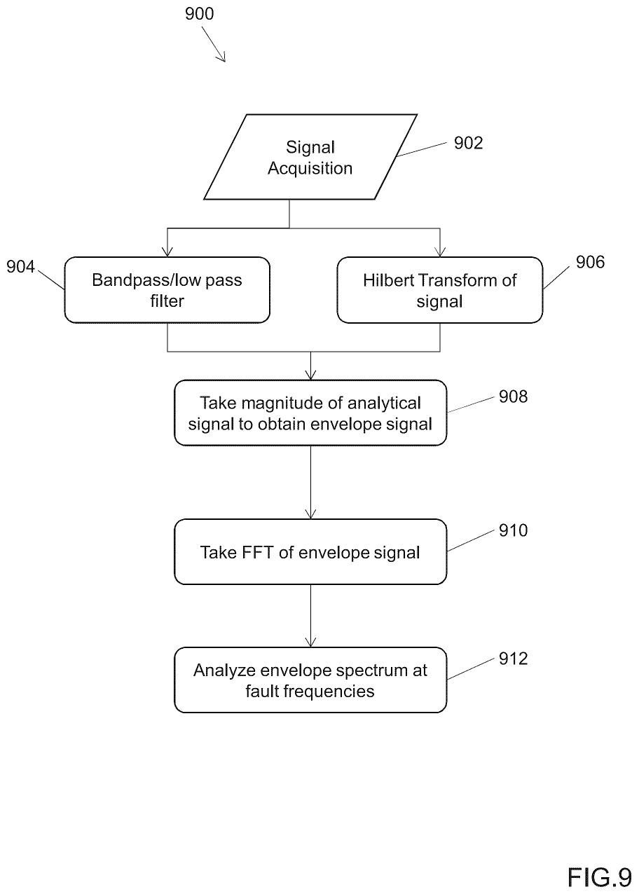

FIG. 9 is a flow chart showing a method of envelope analysis for detection of faults in alternators according to an embodiment of the present invention. The method 900 shown in FIG. 9 may be carried out by the parameter generation module 124 and the analysis module 126 when executed on the processor 102 of the controller 100 shown in FIG. 2.

In step 902, the current signal is received by the controller 100. Following acquisition of the signal in step 902, the method proceeds to either step 904 or step 906 depending on the type of envelope analysis being carried out.

In step 904, filtering is carried out using a bandpass or low pass filter.

In step 906, a Hilbert transform (HT) is applied to the signal. The Hilbert transform (HT) does not involve in a domain change of the signal. HT of a signal x(t) generate another signal denoted here by y(t) will be in the same domain. The HT of a signal x(t) is a signal y(t) whose frequency components lag the frequency component of x(t) by 90°. However, y (t) has exactly the same frequency components with the same amplitude except there is a phase delay of 90°. The Hilbert transform can be calculated as

$$HT of x ( t ) = Acos ( 2 π {f}_{0} t + ∅ )$$

$$Acos ( 2 π {f}_{0} t + ∅ - 90 ° ) = Asin ( 2 π {f}_{0} t + ∅ )$$

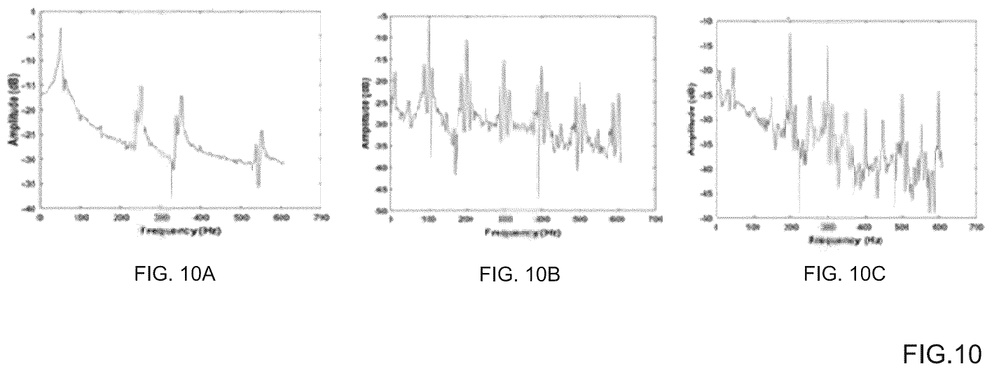

FIG. 10A to FIG. 10C are graphs showing envelope analysis using a Hilbert transform for healthy and faulty alternators. FIG. 10A shows envelope analysis for a healthy alternator, FIG. 10B shows envelope analysis for a faulty-1 alternator an FIG. 10C shows envelope analysis for a faulty-2 alternator. As can be seen from FIG. 10A to FIG. 10C, the faulty alternators have more peaks in amplitude than the healthy alternator.

A further analysis method is time-frequency domain analysis. The wavelet transform is a well-known signal processing technique for the non-stationary signal analysis having transient behaviour. Continuous wavelet transform (CWT) for f (t) is obtained by the sum of all signal multiplied by the scale and shifted form of the wavelet function Ψ(t).

$$C W T ( x , y ) = \frac{1}{\sqrt{\vert x \vert}} {\int }_{- ∞}^{∞} f ( t ) Ψ ( \frac{t - y}{x} ) d t$$

Where, x is a scale parameter and this is inverse of frequency, y represents as translation parameter. Further, the discrete wavelet transform (DWT) is a discretization of CWT and expressed as

$$D W T ( i , j ) = \frac{1}{\sqrt{{2}^{i}}} {\int }_{- ∞}^{∞} f ( t ) Ψ ( \frac{t - {2}^{i} j}{{2}^{i}} ) d t$$

where, the parameters are i, j=1, 2, . . . . High frequencies are associated wide bandwidth, while low frequencies are associated with narrow bandwidth. Using DWT (V_{dwt}), the signal with lower bandwidths and higher bandwidths can be separated which helps in adjusting the resolution at high frequency.

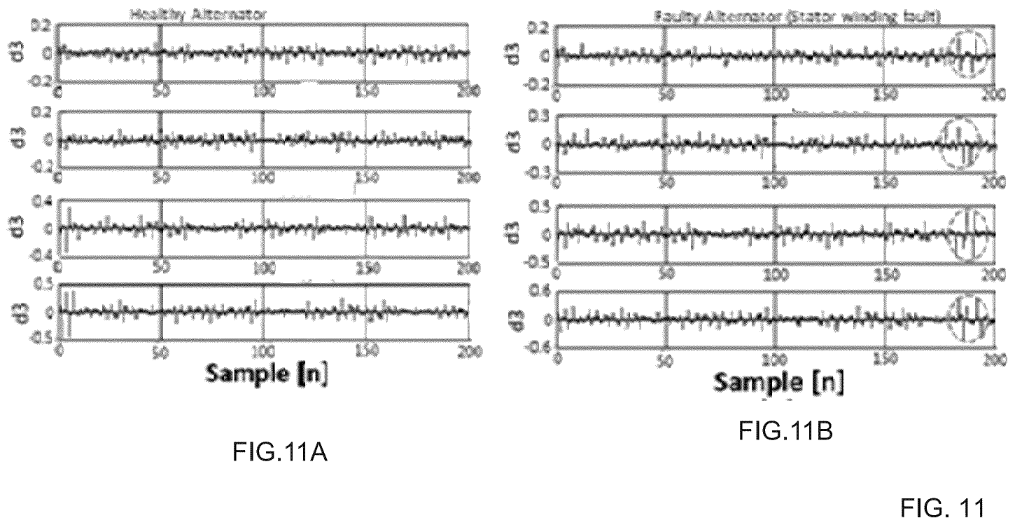

FIG. 11A and FIG. 11B show discrete wavelet transform analysis of signals from a healthy alternator and a faulty alternator. FIG. 11A shows Discrete wavelet Transform of rectified voltage signals for a healthy alternator and FIG. 11B shows Discrete wavelet Transform of rectified voltage signals for a faulty-1 alternator. We can analyse that discrete wavelet transform can be able to detect the stator winding faults in the alternator. It is observed that Daubechies level D4 and D5 can detect the faults as it can notice the changes in coefficient. However, results using the time-frequency domain analysis may not be required for the further analysis and detection of the fault because, using the frequency domain, entropy and envelop analysis itself are able to clearly detect the fault classes. The above analysis can be conducted on both the current signal and the voltage signal.

As described above, numerous parameters can be extracted from the current signal in real-time or near real-time. These parameters may be compared with thresholds as described above in relation to FIG. 4. Alternatively, machine learning techniques may be used to analyze the current signal using the parameters described above as features. Machine learning techniques such as artificial neural network (ANN), support vector machine (SVM) or fuzzy logic (FL) for the prediction and identification of faults in alternators.

In an embodiment, the machine learning algorithm utilizes a neural-fuzzy logic self-cognitive machine learning algorithm that has the self-learning capability from the sensor signal. The training is done by studying failed alternator system in test rig with mimicking defects such as defective bearings, winding fault and imbalance shafts, etc. The test rig provides current, voltage, temperature and vibration type signals which are evaluated by the deep learning algorithm to learn from the signals the degradation and allow the system to self-learn from the observed signals and the information provided regarding the defects created in the system.

When operational, the system monitors the sensor signals along with alarms deduced from the lab study and further from deep learning based unsupervised learning techniques.

The predicted data using machine learning is then transferred to the cloud platform for remote access and control. Any generic cloud platform such as Microsoft azure, amazon web services etc., can be used for this purpose. In this technology disclosure, cloud system is used for remote access, data storage, ML, dashboard display, threshold-based alarm setting and for control purposes. A GUI based front panel on the control station's screen and onboard operational dashboard on the vehicle includes displayed for alert and used to control the parameters from remote room.

The controller and the remote server may communicate through cloud system using Cortex processor. As described above, embodiments of the present invention provide an accurate method to identify and predict alternator faults using current signals.

Whilst the foregoing description has described exemplary embodiments, it will be understood by those skilled in the art that many variations of the embodiments can be made within the scope and spirit of the present invention.

1. A system for monitoring an alternator, the system comprising:
a current sensor configured to measure a current signal from the alternator over time; and
a controller configured to:
extract parameters from the current signal; and
analyze the parameters and thereby identify a potential fault in the alternator.

2. The system according to claim 1, wherein the parameters extracted from the current signal comprise time domain features.

3. The system according to claim 1, wherein the parameters extracted from the current signal comprise frequency domain or envelope features.

4. The system according to claim 3, wherein the parameters comprise envelope features, and wherein extracting the envelope features from the current signal comprises applying a bandpass filter and/or applying a Hilbert transform.

5. The system according to claim 1, wherein the parameters extracted from the current signal comprise entropy features and/or time-frequency domain features.

6. The system according to claim 1, wherein the current sensor is a contactless current sensor.

7. The system according to claim 1, further comprising an interface module configured to generate an alert in response to identifying a potential fault in the alternator.

8. The system according to claim 1, further comprising a communication interface module configured to send the extracted parameters to a remote server.

9. The system according to claim 1, wherein the controller is configured to analyze the parameters by comparing the parameters with one or more thresholds.

10. The system according to claim 1, wherein the controller is configured to analyze the parameters using a machine learning algorithm.

11. A method of monitoring an alternator, the method comprising:
receiving a time varying current signal from the alternator;
extracting parameters from the current signal; and
analyzing the parameters to identify a potential fault in the alternator.

12. The method according to claim 11, wherein the parameters extracted from the current signal comprise time domain features.

13. The method according to claim 11, wherein the parameters extracted from the current signal comprise frequency domain or envelope features.

14. The method according to claim 13, wherein the parameters comprise envelope features, and wherein extracting the envelope features from the current signal comprises applying a bandpass filter and/or applying a Hilbert transform.

15. The method according to claim 11, wherein the parameters extracted from the current signal comprise entropy features and/or time-frequency domain features.

16. The method according to claim 11, further comprising an generating an alert in response to identifying a potential fault in the alternator.

17. The method according to claim 11, further comprising sending the extracted parameters to a remote server.

18. The method according to claim 11, wherein analyzing the parameters comprises comparing the parameters with one or more thresholds.

19. The method according to claim 11, wherein analyzing the parameters comprises using a machine learning algorithm.

20. A computer readable medium carrying processor executable instructions which when executed on a processor cause the processor to carry out a method according to claim 11.
